(19) United States
(12) Patent Application Publication
(10) Pub. No.: US 2008/0136460 A1
(43) Pub. Date: Jun. 12, 2008

(54) Comparator

(75) Inventors: Masayu Fujiwara, Kyoto (JP); Kenya Nakamura, Kyoto (JP)

Correspondence Address: FISH & RICHARDSON P.C., P.O. BOX 1022, MINNEAPOLIS, MN, 55440-1022, US

(73) Assignee: Rohm Co., Ltd., Kyoto (JP)

(21) Appl. No.: 11/952,214

(22) Filed: Dec. 7, 2007

(30) Foreign Application Priority Data
Dec. 7, 2006 (JP) 2006-330229

(51) Int. Cl. H03K 5/22

(52) U.S. Cl. 327/77

(57) ABSTRACT

A comparator has: an offset setting portion adapted to set an offset voltage; an offset subtracting portion adapted to subtract the offset voltage from a non-inverting input voltage; and a comparing portion adapted to shift the output logic level thereof according to which of the output voltage of the offset subtracting portion and an inverting input voltage is higher.

This application is based on Japanese Patent Application No. 2006-330229 filed on Dec. 7, 2006, the contents of which are hereby incorporated by reference.

### BACKGROUND OF THE INVENTION

1. Field of the Invention

The present invention relates to an offset comparator.

2. Description of Related Art

Conventionally, offset comparators are used in various applications. An offset comparator shifts its logic output COMP_OUT between a high and a low level according to whether or not the difference (Vinp−Vinn) between the input voltages Vinp and Vinn thereto is greater than a predetermined offset voltage Voffset (see FIG. 5).

One way to produce such an offset is to intentionally break, in such a way as to obtain the desired offset voltage Voffset, the balance between the differential pair (see FIG. 6, transistors 104 and 105) that constitutes the input stage of a comparator.

Another way is, as shown in FIG. 7, to use a subtractor circuit (resistors 203-206 and an amplifier 207) to find the difference Vo (=Vinp−Vinn) between input voltages Vinp and Vinn and feed it to a comparator circuit 208 to compare it with a predetermined reference voltage Vref (corresponding to an offset voltage Voffset). Here, the resistances (Ra, Rb, Rc, and Rd) of the resistors 203-206 constituting the subtractor circuit are so set as to fulfill the relation Rb/Ra=Rd/Rc (for example, Ra=Rb=Rc=Rd).

As an example of prior art related to the foregoing, JP-A-H06-053299 discloses and proposes a technique according to which the voltage across a current detection resistor is fed to a differential amplifier circuit and its output voltage is compared with a reference voltage (current setting level) to detect overcurrent.

Certainly, with the conventional configurations mentioned above, it is possible to realize an offset comparator easily.

Inconveniently, however, the conventional configurations have the following drawbacks. The configuration relying on breaking the balance between the transistors 104 and 105 shown in FIG. 6 is susceptible to fabrication variations in component devices and to temperature variations, and suffers from variations as large as ±50% or more in the offset voltage Voffset, making it impossible to use the configuration in products with strict requirements (for example, with the tolerated variations being ±40% or less. Incidentally, adopting the rail-to-rail configuration, in which the differential pair constituting the input stage of a comparator is built with both P-channel and N-channel transistors, helps widen the input dynamic range of the comparator, but is of no help to reduce variations in the offset voltage Voffset.

On the other hand, the comparator shown in FIG. 7 would pose no particular problem if the resistors 203-206 constituting the subtractor circuit could be built with real devices to obtain the desired resistance ratio (for example, with variations of ±5% or less). In reality, however, it is extremely difficult to fabricate the devices so that relative variations in the resistance ratio is smaller than ±5%. If the resistance ratio has relative variations of ±5%, in the comparator shown in FIG. 7, due to its circuit configuration, in the worst case, variations of ±20-30% may appear in the difference Vo between the input voltages Vinp and Vinn, and these, combined with variations (about ±10%) in the reference voltage Vref, may bring variations of about 30-40% in the offset voltage Voffset. Thus, in view of the current trend toward increasingly strict requirements in products, the conventional configuration shown in FIG. 7 is no longer satisfactory. It is therefore necessary to further reduce variations.

### SUMMARY OF THE INVENTION

In view of the above inconveniences, it is an object of the present invention to provide an offset comparator in which variations in the offset voltage can be satisfactorily reduced.

To achieve the above object, according to the present invention, a comparator is provided with: an offset setting portion adapted to set an offset voltage; an offset subtracting portion adapted to subtract the offset voltage from a non-inverting input voltage; and a comparing portion adapted to shift the output logic level thereof according to which of the output voltage of the offset subtracting portion and an inverting input voltage is higher.

Other features, elements, steps, advantages and characteristics of the present invention will become more apparent from the following detailed description of preferred embodiments thereof with reference to the attached drawings.

### BRIEF DESCRIPTION OF THE DRAWINGS

FIG. 1 is a circuit diagram showing the comparator of a first embodiment of the present invention;

FIG. 2 is a circuit diagram showing the comparator of a second embodiment of the present invention;

FIGS. 3A to 3D are diagrams illustrating the behavior of an offset voltage Voffset;

FIG. 4 is a circuit diagram showing the comparator of a third embodiment of the present invention;

FIG. 5 is a block diagram showing an offset comparator;

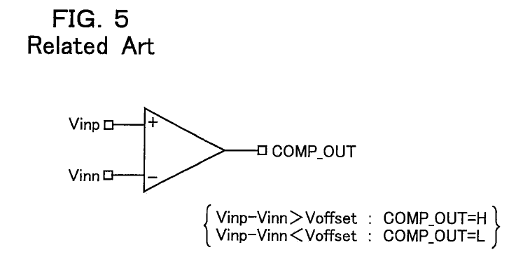

FIG. 6 is a circuit diagram of a conventional example of an offset comparator; and

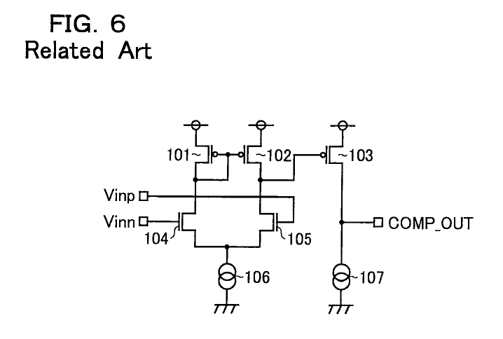

FIG. 7 is a circuit diagram of another conventional example of an offset comparator

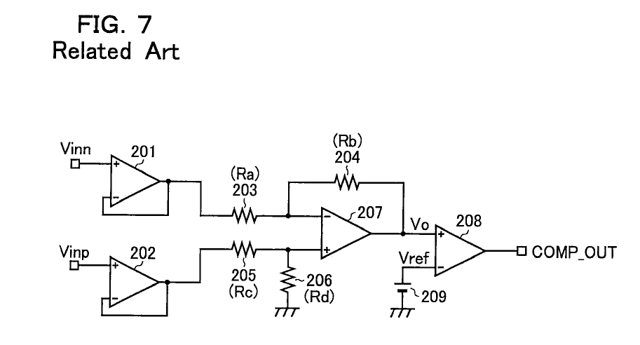

### DETAILED DESCRIPTION OF PREFERRED EMBODIMENTS

First, the comparator of a first embodiment of the present invention will be described in detail with reference to the drawings.

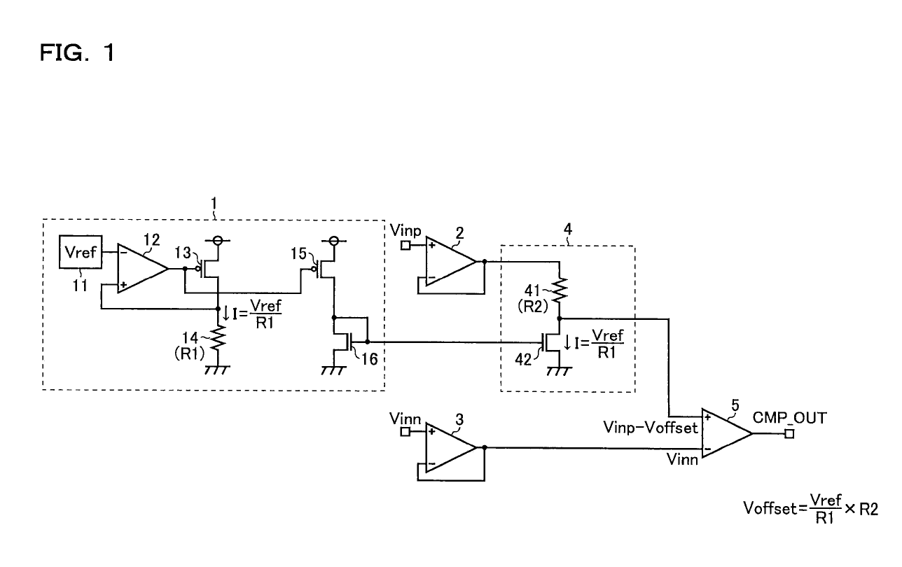

FIG. 1 is a circuit diagram showing the comparator of the first embodiment of the invention.

As shown FIG. 1, the comparator of this embodiment has an offset setting portion 1, a buffer portion 2, a buffer portion 3, an offset subtracting portion 4, and a comparing portion 5.

The offset setting portion 1 serves as means for setting the offset voltage Voffset of the comparator, and has a reference voltage source 11, an amplifier 12, a P-channel field-effect transistor 13, a resistor 14 (with a resistance of R1), a P-channel field-effect transistor 15, and an N-channel field-effect transistor 16.

In the offset setting portion 1, the inverting input terminal (−) of the amplifier 12 is connected to the output terminal of the reference voltage source 11 to receive a reference voltage Vref. The non-inverting input terminal (+) of the amplifier 12 is connected to the drain of the transistor 13, and is also connected through the resistor 14 to a grounded node. The output terminal of the amplifier 12 is connected to the gate of each of the transistors 13 and 15. The sources of the transistors 13 and 15 are both connected to a supplied-power node. The drain of the transistor 15 is connected to the drain and gate of the transistor 16. The source of the transistor 16 is connected to the grounded node.

The buffer portion 2 serves as means for buffering and amplifying the non-inverting input voltage Vinp to the comparator.

The buffer portion 3 serves as means for buffering and amplifying the inverting input voltage Vinn to the comparator.

The offset subtracting portion 4 serves as means for subtracting the offset voltage Voffset from the non-inverting input voltage Vinp, and has a resistor 41 (with a resistance of R2) and an N-channel field-effect transistor 42.

In the offset subtracting portion 4, one end of the resistor 41 is connected to the output terminal of the buffer portion 2 (and hence to the node to which the non-inverting input voltage Vinp is applied). The other end of the resistor 41 is connected to the drain of the transistor 42. The gate of the transistor 42 is connected to the gate of the transistor 16. The source of the transistor 42 is connected to the grounded node.

The comparing portion 5 serves as means for shifting its output logic level COMP_OUT according to which of the output voltage (Vinp−Voffset) of the offset subtracting portion 4, which the comparing portion 5 receives at its non-inverting input terminal (+), and the inverting input voltage Vinn, which the comparing portion 5 receives at its inverting input terminal (−), is higher.

The comparator configured as described above operates as follows. In the offset setting portion 1, the amplifier 12 turns the transistor 13 on and off so that the voltage at one end of the resistor 14 remains equal to the reference voltage Vref. As a result, the resistor 14 constantly receives at one end the reference voltage Vref, and thus produces a predetermined constant current I (=Vref/R1). The transistor 15 is turned on and off in the same manner as the transistor 13 is, with the result that the transistor 15 outputs at its drain the same constant current I.

On the other hand, in the offset subtracting portion 4, the transistor 42, along with the transistor 16 of the offset setting portion 1, forms a current mirror circuit. Thus, as the constant current I is passed through the resistor 41 toward the grounded node, the offset voltage Voffset, which corresponds to the voltage drop (I×R2=(Vref/R1)×R2) across the resistor 41 is subtracted from the non-inverting input voltage Vinp.

If the output voltage (Vinp−Voffset) of the offset subtracting portion 4 is higher than the inverting input voltage Vinn, the comparing portion 5 shifts its output logic COMP_OUT to a high level; if the output voltage (Vinp−Voffset) of the offset subtracting portion 4 is lower than the inverting input voltage Vinn, the comparing portion 5 shifts its output logic COMP_OUT to a low level.

As described above, the comparator of this embodiment is configured as follows. The offset voltage Voffset is subtracted from the non-inverting input voltage Vinp, and the result is compared with the inverting input voltage Vinn. Here, the offset voltage Voffset is set according to the reference voltage Vref and the resistance ratio (R2/R1).

Adopting this configuration offers the following benefit. For example, even when the reference voltage Vref has variations of ±10% and the resistance ratio (R2/R1) has variations of ±5%, the offset voltage Voffset has, at most, the simple sum of those variations, i.e., variations of about ±15%. Thus, it is possible to meet strict requirements in products.

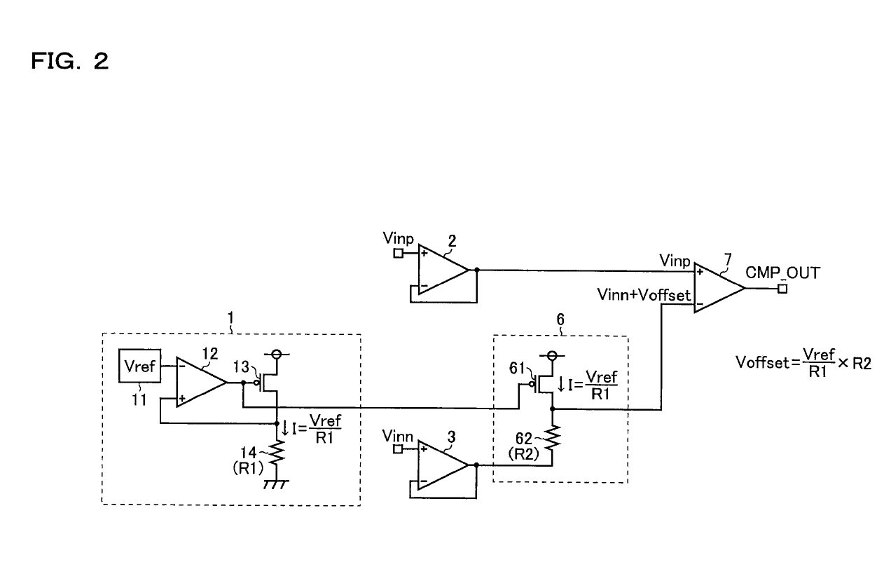

Next, the comparator of a second embodiment of the present invention will be described in detail with reference to FIG. 2.

FIG. 2 is a circuit diagram showing the comparator of the second embodiment of the invention.

As shown in FIG. 2, the comparator of this embodiment is characterized in having, instead of the offset subtracting portion 4 and the comparing portion 5 described previously, an offset adding portion 6 and a comparing portion 7.

Accordingly, such components as find their counterparts in the first embodiment are identified by reference signs common to FIG. 1, and overlapping description will not be repeated. The following description thus centers around the features unique to this embodiment (the introduction of the offset adding portion 6).

The offset adding portion 6 serves as means for adding the offset voltage Voffset to the inverting input voltage Vinn, and has a P-channel field-effect transistor 61 and a resistor 62 (with a resistance of R2).

In the offset adding portion 6, one end of the resistor 62 is connected to the output terminal of the buffer portion 3 (and hence to the node to which the inverting input voltage Vinn is applied). The other end of the resistor 62 is connected to the drain of the transistor 61. The gate of the transistor 61 is connected to the output terminal of the amplifier 12 provided in the offset setting portion 1. The source of the transistor 61 is connected to the supplied-power node. Incidentally, the omission of the offset subtracting portion 4 is accompanied by the omission of transistors 15 and 16 from the offset setting portion 1.

The comparing portion 7 serves as means for shifting its output logic level COMP_OUT according to which of the output voltage (Vinn+Voffset) of the offset adding portion 6, which the comparing portion 7 receives at its inverting input terminal (−), and the non-inverting input voltage Vinp, which the comparing portion 7 receives at its non-inverting input terminal (+), is higher.

The comparator configured as described above operates as follows. In the offset adding portion 6, the transistor 61 is turned on and off in the same manner as the transistor 13 is, with the result that the transistor 61 outputs at its drain a predetermined constant current I (=Vref/R1). Thus, in the offset adding portion 6, as the constant current I is passed through the resistor 62 from the supplied-power node, the offset voltage Voffset, which corresponds to the voltage rise (I×R2=(Vref/R1)×R2) across the resistor 62 is added to the inverting input voltage Vinn.

If the output voltage (Vinn+Voffset) of the offset adding portion 6 is higher than the non-inverting input voltage Vinp, the comparing portion 5 shifts its output logic COMP_OUT to a high level; if the output voltage (Vinn+Voffset) of the offset adding portion 6 is lower than the non-inverting input voltage Vinp, the comparing portion 5 shifts its output logic COMP_OUT to a low level.

As described above, the comparator of this embodiment is configured as follows. The offset voltage Voffset is added to the inverting input voltage Vinn, and the result is compared with the non-inverting input voltage Vinp. Here, the offset voltage Voffset is set according to the reference voltage Vref and the resistance ratio (R2/R1).

Adopting this configuration offers the following benefit. For example, even when the reference voltage Vref has variations of +10% and the resistance ratio (R2/R1) has variations of ±5%, as in the first embodiment described previously, the offset voltage Voffset has, at most, the simple sum of those variations, i.e., variations of about ±15%. Thus, it is possible to meet strict requirements in products.

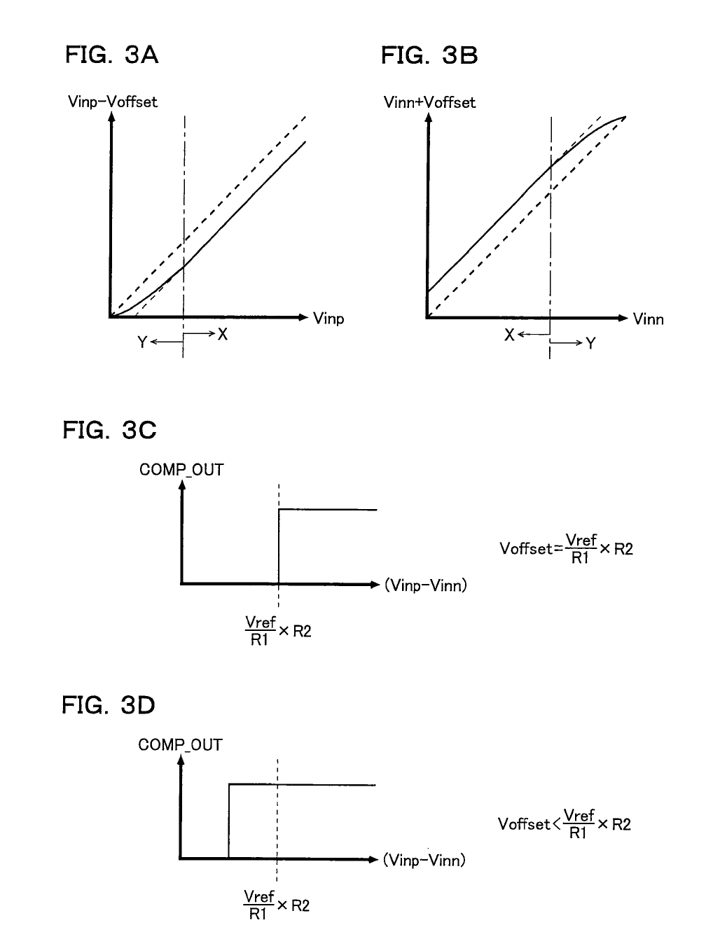

In a case where the first embodiment described previously is adopted, so long as the non-inverting input voltage Vinp is sufficiently high, the output voltage (Vinp−Voffset) obtained from the offset subtracting portion 4 exhibits satisfactory linearity; thus, the offset voltage Voffset has the intended set level ((Vref/R1)×R2) (see the voltage range X in FIG. 3A, and FIG. 3C). Likewise, in a case where the second embodiment described above is adopted, so long as the inverting input voltage Vinn is sufficiently low, the output voltage (Vinn+Voffset) obtained from the offset adding portion 6 exhibits satisfactory linearity; thus, the offset voltage Voffset has the intended set level ((Vref/R1)×R2) (see the voltage range X in FIG. 3B, and FIG. 3C).

If the above conditions are not fulfilled, that is, if the non-inverting input voltage Vinp is so low that the offset voltage Voffset can no longer be subtracted from it or, reversely, if the inverting input voltage Vinn is so high that the offset voltage Voffset can no longer be added to it, in the first and second embodiments described above, the offset subtracting portion 4 and the offset adding portion 6 cannot maintain satisfactory linearity, causing the offset voltage Voffset to be lower than the intended set level ((Vref/R1)×R2) (see the voltage range Y in FIGS. 3A and 3B, and FIG. 3D).

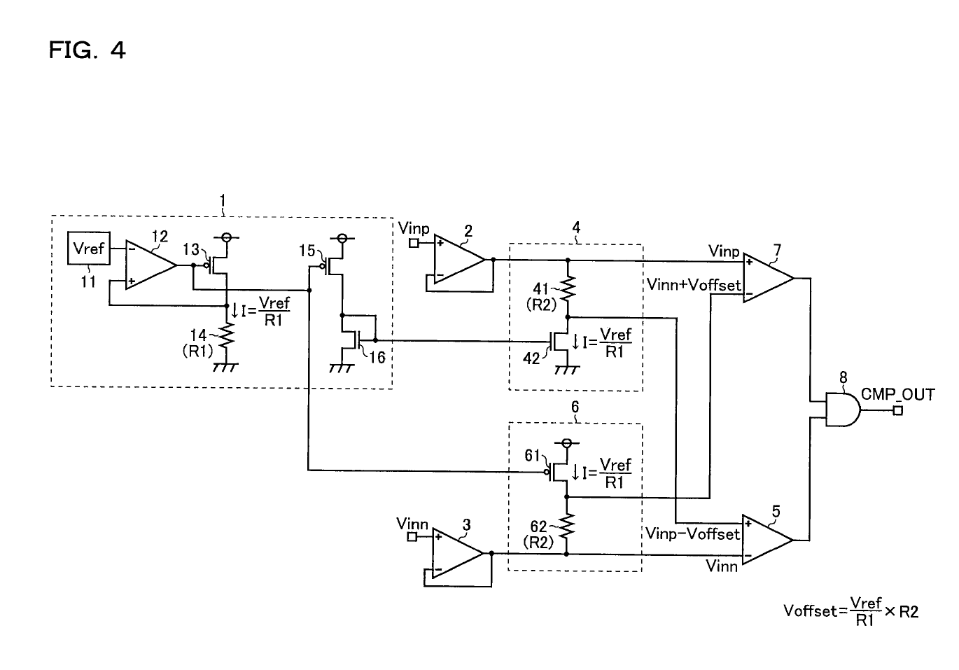

To avoid this, in the comparator of a third embodiment of the present invention, as shown in FIG. 4, the configuration of the first embodiment (with the offset subtracting portion 4 and the comparing portion 5) and that of the second embodiment (with the offset adding portion 6 and the comparing portion 7) are added up, and in addition an AND operation portion 8 is further provided to perform an AND operation between the comparison output of the comparing portion 5 and that of the comparing portion 7.

With this configuration, when the output logic levels of the comparing portions 5 and 7 are both at a high level, the output logic level COMP_OUT of the comparator is shifted to a high level. Thus, based on whichever exhibits higher linearity of the output voltage (Vinp−Voffset) of the offset subtracting portion 4 and the output voltage (Vinn+Voffset) of the offset adding portion 6, the offset voltage Voffset is set. Accordingly, the comparator of this embodiment offers a uniform offset over its entire input dynamic range.

Moreover, the comparator of this embodiment has a single offset setting portion 1 for both the offset subtracting portion 4 and the offset adding portion 6. This eliminates the risk of an unnecessary variation occurring between the constant current I fed to the offset subtracting portion 4 and the constant current I fed to the offset adding portion 6, and in addition helps avoid an unnecessary increase in circuit scale.

It should be understood that the present invention can be practiced otherwise than specifically described by way of embodiments above, with any modifications and variations made within the spirit of the invention.

In terms of its benefits, the present invention offers comparators in which variations in the offset voltage can be satisfactorily reduced and that can thus meet strict requirements in products.

In terms of its industrial applicability, the present invention is useful in reducing variations in the offset voltage in offset comparators.

While the present invention has been described with respect to preferred embodiments, it will be apparent to those skilled in the art that the disclosed invention may be modified in numerous ways and may assume many embodiments other than those specifically set out and described above. Accordingly, it is intended by the appended claims to cover all modifications of the present invention which fall within the true spirit and scope of the invention.

What is claimed is:

1. A comparator comprising:
an offset setting portion adapted to set an offset voltage;
an offset subtracting portion adapted to subtract the offset voltage from a non-inverting input voltage; and
a comparing portion adapted to shift an output logic level thereof according to which of an output voltage of the offset subtracting portion and an inverting input voltage is higher.

2. A comparator of claim 1,
wherein the offset setting portion produces a predetermined constant current by applying a reference voltage to a first resistor.

3. A comparator of claim 2,
wherein the offset subtracting portion passes the predetermined constant current through a second resistor, of which one end is connected to a node to which the non-inverting input voltage is applied, toward a grounded node and thereby subtracts from the non-inverting input voltage the offset voltage, which corresponds to a voltage drop across the second resistor.

4. A comparator comprising:
an offset setting portion adapted to set an offset voltage;
an offset adding portion adapted to add the offset voltage to an inverting input voltage; and
a comparing portion adapted to shift an output logic level thereof according to which of an output voltage of the offset adding portion and a non-inverting input voltage is higher.

5. A comparator of claim 4,
wherein the offset setting portion produces a predetermined constant current by applying a reference voltage to a first resistor.

6. A comparator of claim 5,
wherein the offset adding portion passes the predetermined constant current through a second resistor, of which one end is connected to a node to which the inverting input voltage is applied, from a supplied-power node and thereby adds to the inverting input voltage the offset voltage, which corresponds to a voltage rise across the second resistor.

7. A comparator comprising:
an offset setting portion adapted to set an offset voltage;
an offset subtracting portion adapted to subtract the offset voltage from a non-inverting input voltage;
a first comparing portion adapted to shift an output logic level thereof according to which of an output voltage of the offset subtracting portion and an inverting input voltage is higher;
an offset adding portion adapted to add the offset voltage to the inverting input voltage;
a second comparing portion adapted to shift an output logic level thereof according to which of an output voltage of the offset adding portion and the non-inverting input voltage is higher; and
an AND operation portion adapted to perform an AND operation between a comparison output of the first comparing portion and a comparison output of the second comparing portion.

8. A comparator of claim 7,
wherein the offset setting portion produces a predetermined constant current by applying a reference voltage to a first resistor.

9. A comparator of claim 8,
wherein the offset subtracting portion passes the predetermined constant current through a second resistor, of which one end is connected to a node to which the non-inverting input voltage is applied, toward a grounded node and thereby subtracts from the non-inverting input voltage the offset voltage, which corresponds to a voltage drop across the second resistor.

10. A comparator of claim 8,
wherein the offset adding portion passes the predetermined constant current through a second resistor, of which one end is connected to a node to which the inverting input voltage is applied, from a supplied-power node and thereby adds to the inverting input voltage the offset voltage, which corresponds to a voltage rise across the second resistor.
